(19) United States
(12) Patent Application Publication
(10) Pub. No.: US 2025/0199513 A1
(43) Pub. Date: Jun. 19, 2025

(54) COOLING SYSTEM CONTROL FOR DATA CENTER HEAT REUSE

(71) Applicant: ZUTA-CORE LTD., Hof Ashkelon (IL)

(72) Inventor: Shahar BELKIN, Kibutz Bror Hayil (IL)

(21) Appl. No.: 18/845,342

(22) PCT Filed: Mar. 5, 2023
(86) PCT No.: PCT/IL2023/050224

§ 371 Date: Sep. 9, 2024

Related U.S. Application Data
(60) Provisional application No. 63/317,807, filed on Mar. 8, 2022.

(51) Int. Cl. G05B 19/4155

(52) U.S. Cl. CPC G05B 19/4155; G05B 2219/50333

(57) ABSTRACT

A system and methods are provided for controlling data center heat reuse. The system includes multiple evaporators units (EUs), each configured to operate as a two-phase evaporator, each EU affixed to a central processing unit (processing unit) package of a data center server to draw heat from the processing unit packages. The system further includes a heat reuse unit (HRU) condenser, configured to provide refrigerant liquid to the multiple EUs and to receive heated refrigerant from the multiple EUs, and further configured to release heat from the heated refrigerant to an HRU medium providing heat to a reuse application; and an HRU controller, including programmed instructions that when executed by the HRU controller perform steps reducing a rate of HRU medium flow by increments, such that the temperature of all processing units is incrementally increased in a balanced manner to maximize the refrigerant temperature for heat reuse.

### FIELD OF THE INVENTION

The present invention generally relates to the field of room cooling, in particular data center cooling and heat reuse.

### BACKGROUND

As the demands for data processing, data storage, and telecommunications have skyrocketed over the past few decades, the data center industry has seen dramatic growth. Data centers are a major source of energy consumption globally, consuming an estimated 2% of all electricity produced.

Given the high cost of energy and the environmental impact of electricity production, data center owners continue to seek ways to reduce the energy requirements of their facilities. Manufacturers of data processing equipment have supported the effort by continuing to find ways of reducing the energy required for a given data processing load. Data center energy efficiency can also be improved by reusing the heat that they generate. Heat from data centers can be reused to heat both air and water for residential and commercial buildings. A number of projects around the world also use “waste” heat for district heating.

Most air conditioning systems that extract heat from data centers provide that heat as relatively low temperature air or water, reducing the potential efficiency benefits. Typically, the heat must be further processed by heat pumps to be effective Heated air is an especially inefficient way of transferring heat over any significant distant.

Methods are therefore needed to improve the “quality” of waste heat, to facilitate more efficient reuse.

### SUMMARY

Embodiments of the present invention provide a system and methods for cooling system control for data center heat reuse. Embodiments may include multiple evaporators units (EUs), each configured to operate as a two-phase evaporator, each of the multiple EUs affixed to a respective processing unit package of a data center server to draw heat from the respective processing unit package; a heat reuse unit (HRU) condenser, configured to provide refrigerant liquid to the multiple EUs and to receive heated refrigerant vapor from the multiple EUs, and further configured to release heat from the heated refrigerant vapor to an HRU medium providing heat to a reuse application; and an HRU controller, including non-transient memory storage having programmed instructions to perform an iterative process of controlling temperatures of the processing unit packages. The process may include steps of:
1) receiving temperature and frequency data from all processing units of the processing unit packages;
2) determining that a number of processing units that are thermally and/or user-throttled is less than a preset maximum of throttled processing units (X₁) and that at least one processing unit is thermally throttled by more than a preset upper thermal throttle limit (X₂);
3) responsively signaling the HRU condenser to increase a rate of HRU medium flow by a preset increase flow increment (X₃);
4) subsequently signaling all processing units that are thermally throttled by at least a preset lower thermal throttle limit (X₅) to reduce their user-throttled maximum frequency by a preset user-throttle increment (X₄);
5) subsequently, signaling the HRU condenser to reduce the rate of HRU medium flow by a preset decrease flow increment (X₆);
6) repeating the above steps until determining at step 2 that the number of thermally and user throttled processing units is at least equal to the preset maximum of throttled processing units (X₁).

The instructions may further include an alternative process of determining at step 2 that no processing units are thermally throttled by more than the preset outlier thermal throttle limit (X₂) and responsively proceeding directly to step 5.

The instructions may also further include maintaining the rate of HRU medium flow and the user maximum processing unit frequency settings, responsively to determining at step 2 that the number of thermally and user throttled processing units is at least equal to the preset maximum of throttled processing units (X₁).

The instructions may also further include outputting statistics of processing unit temperatures, including mean and standard deviation of processing unit temperatures, responsively to determining at step 2 that the number of thermally and user throttled processing units is at least equal to the preset maximum of throttled processing units (X₁).

In some embodiments, the preset maximum of throttled processing units (X₁) is preset at a level to maintain service level agreement (SLA) requirements. Also in some embodiments, the preset maximum of throttled processing units (X₁) is set to between 20 and 40 percent, for example, 30 percent. The preset upper thermal throttle limit (X₂) may be set, in some embodiments, to between 5 and 20 percent, for example, 10 percent.

In some embodiments, the preset increase flow increment (X₃) is set to between 1 and 10 percent, for example, 5 percent.

In some embodiments, the preset user throttle increment (X₄) is set to between 1 and 10 percent, for example, 5 percent.

In some embodiments, the preset lower thermal throttle limit (X₅) is set to between 1 and 10 percent, for example, 5 percent.

In some embodiments, the preset decrease flow increment (X₆) is set to between 1 and 10 percent, for example, 5 percent.

### BRIEF DESCRIPTION OF DRAWINGS

For a better understanding of various embodiments of the invention and to show how the same may be carried into effect, reference will now be made, by way of example, to the accompanying drawings. Structural details of the invention are shown to provide a fundamental understanding of the invention, the description, taken with the drawings, making apparent to those skilled in the art how the several forms of the invention may be embodied in practice. In the figures:

FIG. 1 is a schematic diagram of a system for data center heat reuse, in accordance with an embodiment of the present invention;

FIGS. 2A and 2B are schematic diagrams of heat flow in a system for data center heat reuse, in accordance with an embodiment of the present invention; and

FIG. 3 is a flow diagram of a process for controlling data center heat reuse, in accordance with an embodiment of the present invention.

### DETAILED DESCRIPTION

It is to be understood that the invention is not necessarily limited in its application to the details of construction and the arrangement of the components and/or methods set forth in the following description and/or illustrated in the drawings. The invention is capable of other embodiments or of being practiced or carried out in various ways.

Embodiments of the present invention provide methods for improving power efficiency of a data center. Illustrative embodiments of the invention are described below. In the interest of clarity, not all features or components of an actual implementation are necessarily described. Embodiments and/or limitations featured in the figures are chosen for convenience or clarity of presentation and are not meant to limit the scope of the invention.

Hereinbelow, the term “server” refers to a computer with one or more processing units (PUs), such as central processing units (processing units) or graphics processing units (GPUs). A “data center rack” is meant to indicate a unit with which multiple servers are associated. A rack may be a frame upon which multiple servers are mounted. However, hereinbelow, a data center rack exemplifies any configuration of multiple servers in a data center that are drawing refrigerant from a single heat reuse (HRU) condenser, that is, the configuration described below with respect to a rack may also be applied to multiple racks, such as an “isle” of a data center, or to an entire data center, as described below.

Liquid cooling systems (e.g., water-based, direct-on-chip systems) are generally configured to support a given “thermal design power” or “thermal design point” (TDP) that supports cooling of processing units operating at their maximum level of heat generation. Even under “full load” conditions, the temperature and flow of the coolant (e.g., water or refrigerant) must be sufficient such that processing unit temperatures (i.e., temperatures at the junction, referred to herein as the “Tjunction” between the processing unit chip and the processing unit package) are kept below maximum values set by the manufacturer. Modern processing units are configured to implement “thermal throttling,” that is, they reduce their energy consumption as their temperatures reach their maximum values. Typically the thermal throttling is implemented by reducing operating clock rates, i.e., operating frequencies. Thermal throttling therefore reduces system performance.

Servers as described hereinbelow are also assumed to be configured to accept user instructions to change processing unit clock speeds. Such user-initiated throttling, referred to hereinbelow as user-throttling, may change any one or more of several clock parameters, such as core, front side bus (FSB), and clock multiplier rates. processing unit voltages may also be modifiable to support clock changes and energy consumption levels.

Because coolant systems are typically working the same both for processing units operating at their maximum level and for processing units that are only partially loaded, the coolant is typically heated to different temperatures by different processing units. When coolant flow from multiple processing units is then mixed in a heat exchanger to release the heat energy, the resulting temperature is typically too low for effective heat reuse. Given the typical fluctuation of data center loads, the coolant temperature also varies, such that it is not possible to predict the availability of effective heat for reuse.

It should be noted that different chip technologies and TDP values dictate different maximum temperatures for processing units and for processing unit packages (referred to herein as “Tcase”). The technology having the lowest maximum Tcase value is the technology by which coolant temperatures should be set, thereby preventing processing unit temperatures from exceeding maximum allowable values.

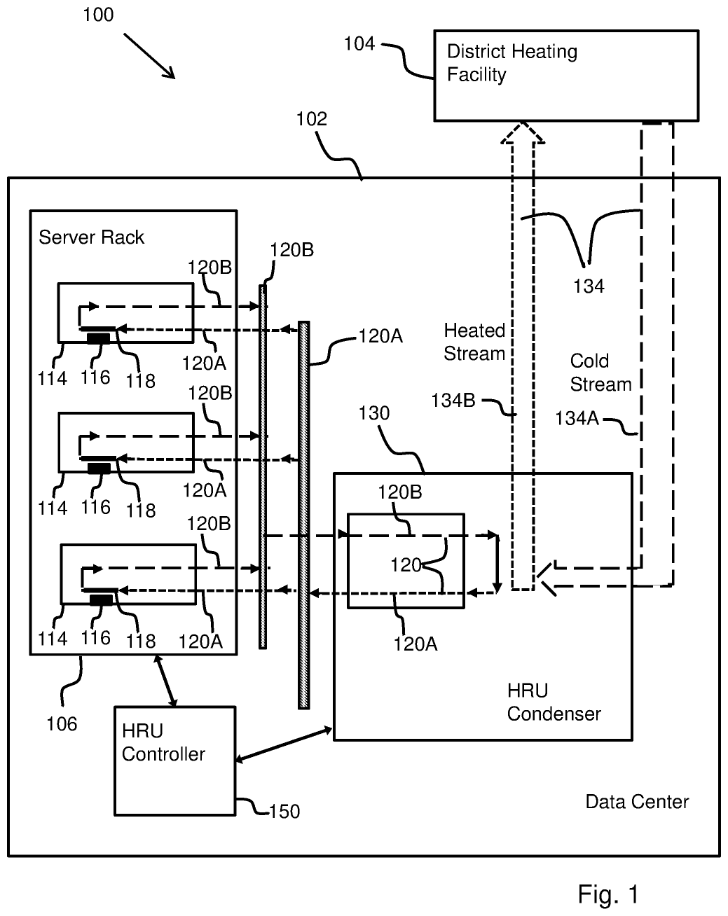

FIG. 1 is a schematic diagram of a system 100 for controlling data center heat reuse, in accordance with an embodiment of the present invention. System 100 includes a data center 102 that supplies reuse heat to one or more external applications, such as a district heating facility 104. The district heating facility may be one or more buildings, such as a residential community.

The data center includes multiple server racks, such as server rack 106, on which are mounted multiple servers 114. Each server includes one or more processing unit packages 116, which include processing units (also referred to as processing unit chips, or “dies”). As the processing units operate, they emit heat to the processing unit packages 116 that must be dissipated in order to prevent overheating. In embodiments of the present invention, a two-phase evaporator 118, also referred to hereinbelow as an evaporator or “evaporator unit” (EU), is mounted to each processing unit package 116 to absorb the generated heat.

A refrigerant 120 is circulated in the system 100 to absorb the heat in the evaporator 118, and to release the heat in a heat reuse (HRU) condenser 130 (also referred to hereinbelow as a heat exchanger). When the refrigerant 120 enters the two-phase evaporator 118, as indicated by arrows on the refrigerant cycle, the refrigerant is in a liquid state 120A. Heat absorbed in the evaporator 118 converts the refrigerant, at least partially, to a superheated state 120B (i.e., partial or complete vapor).

From the evaporator 118, the refrigerant flows in the superheated state 120B to the HRU condenser 130, where it is returned to the liquid state 120A. The heat from the refrigerant is absorbed by an HRU medium 134, such as air or water, which in turn provides heat to the district heating facility 104. The HRU medium (also referred to herein as the condenser medium) enters the HRU condenser as a cold stream 134A and is ejected to the district heating facility 104 as a heated stream 134B.

System 100 also includes an HRU controller 150 that may be any dedicated or general-purpose computer that is configured to control the operation of the HRU condenser 130 and of the processing units of the processing unit packages 116, according to data collected from the processing units. In particular, HRU controller receives temperature and frequency data from all processing units of the processing unit packages 116. Subsequently, the HRU controller manages maximum processing unit frequencies, as well as HRU medium 134 flow rates, as described further hereinbelow, in order to achieve an optimal level of heat generation. Hereinbelow, the “optimal level of heat generation” indicates a level of data center operation that produces a waste heat at a high temperature efficient heat for reuse, without causing an unacceptable decline in data center performance. Typically, parameters of operation lead to some thermal and user throttling, but at a level that does not prevent the data center from meeting service level agreement (SLA) requirements.

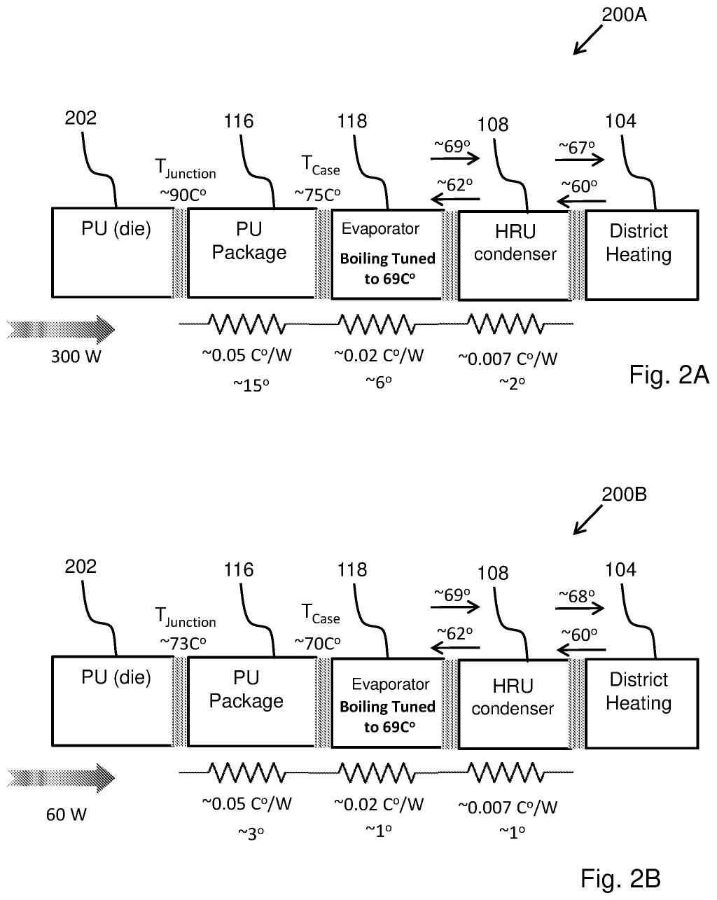

FIGS. 2A and 2B are schematic diagrams of heat flow in the system 100, in accordance with an embodiment of the present invention. Shown in each figure is heat flow from a representative one of processing unit (PU) packages 116 (i.e., one of the multiple processing unit packages 116 described above). Heat generated by each processing unit package 116 is generated by a respective processing unit 202 that is encased in the processing unit package 116. The processing unit package releases the heat to a respective evaporator 118. The evaporator, in turn, receives refrigerant from the HRU condenser 108. The evaporator 118 absorbs the processing unit package heat and turns the refrigerant into vapor. The vapor then flows to the HRU condenser 108 that subsequently releases the heat to a heat reuse application such as heating the district heating facility 104, as described above.

FIG. 2A indicates heat flow of an illustrative scenario 200A in which the processing unit 202 is consuming 300 W of power, meaning that 300 W of heat must be dissipated through the processing unit package. The dissipated heat must then be released through each subsequent stage of heat flow until the heat is released to the district heating facility 104.

A given pressure of refrigerant vapor is set by the HRU controller by controlling the condensing speed, which is done by controlling the flow of the HRU medium in the HRU condenser. The vapor pressure determines the boiling temperature in the evaporators. That is, the refrigerant boiling temperature can be tuned by changing the pressure of the vapor in the refrigeration loop. Changing the flow rate of the HRU medium (which may be, for example, water or air) from the external cooling loop changes the condensation rate inside the heat exchanger. A slow condensation rate in the heat exchanger causes the vapor pressure to rise, thereby causing the refrigerant boiling temperature to rise in the evaporator.

The temperature at the processing unit junction, (referred to as the “Tjunction”) is indicated in the exemplary scenario 200A as ˜90° C. With a thermal resistivity through the processing unit package estimated as ˜0.05° C./W, there is a temperature drop through the processing unit package of approximately (0.05° C./W)×(300 W)=15° C. That is, the temperature of the package, indicated as “Tcase,” is ˜90° C. ˜15° C.=˜75° C.

With a thermal resistivity through the evaporator estimated as ˜0.02° C./W, there is a temperature drop of approximately (0.02° C./W)×(300 W)=6° C. That is, the temperature of the refrigerant leaving the evaporator, as indicated, is ˜69° C. The pressure of the refrigerant is typically tuned such that 69° C. is the evaporative temperature (i.e., boiling temperature), thereby providing highly efficient heat absorption at this temperature. As indicated, the refrigerant at the evaporator entrance may be 62° C.

With a thermal resistivity of the a ˜0.02° C./W, there is a temperature drop at the HRU condenser of approximately (0.07° C./W)×(300 W)=˜2° C. This results in a sufficiently high temperature of ˜2° C. for heat reuse.

As indicated in FIG. 2B, in a second scenario 200B of a processing unit operating at a partial load and consuming only 60 W, the evaporator is capable of operating with a similar range of refrigerant temperatures as described above, that is, with an input temperature of ˜62° C. and an output temperature of ˜69° C.

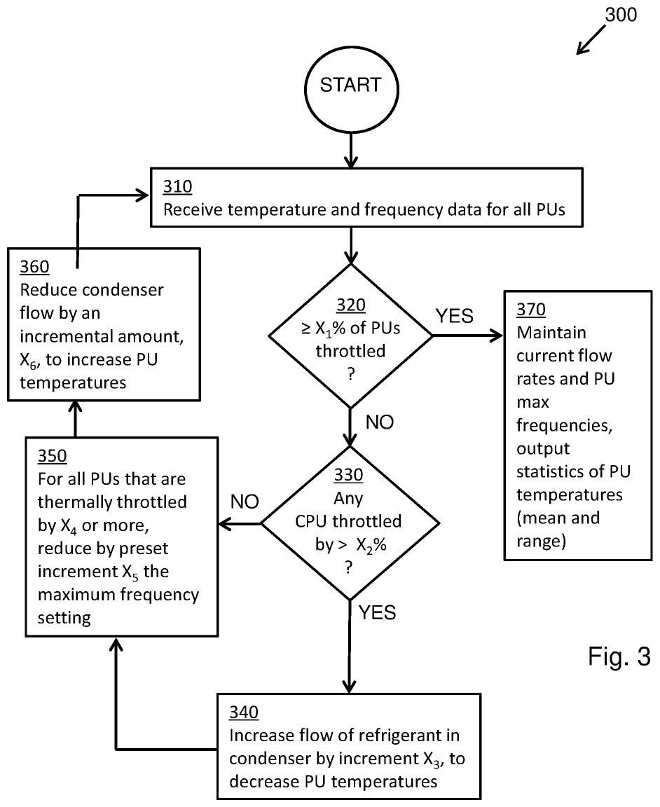

FIG. 3 is a flow diagram of a process 300 for controlling data center heat reuse, in accordance with an embodiment of the present invention. Steps of the process are typically implemented by the HRU controller described above. The process may be an on-going process or may be implemented intermittently, stopping for periods of time once the optimal operating conditions described below are achieved. A system such as system 100 above is assumed, with an HRU condenser providing refrigerant for multiple evaporators units (EUs), each configured to operate as a two-phase evaporator. Typically, each EU is affixed to a package of a central processing unit or graphical processing unit (i.e., a “PU”) to draw heat from the processing unit packages. The condenser is configured to release heat from the heated refrigerant to an HRU medium providing heat to a reuse application.

The process implemented by the HRU controller, as described below, gradually increases the temperature of all processing units, regardless of their load, while optimizing data center throughput performance. Without the process described below, multiple processing units could be thermally throttled at significant levels, while other processing units are operating at low temperature levels that prevent efficient heat reuse.

At a first step 310, the HRU controller receives temperature and frequency data from all processing units.

Based on the received data, at a subsequent step 320, the HRU controller determines whether a preset maximum number of processing units are thermally and/or user-throttled. The preset maximum is typically set to a level that ensures that service level agreement (SLA) requirements can be met.

If the number that are throttled is less than the preset maximum of throttled processing units (X1), then processing continues at a step 330. At this step, the HRU controller determines whether any of the throttled processing units are throttled by more than a preset upper thermal throttle limit (X2).

If any of the throttled processing units are throttled by more than the upper thermal throttle limit, then processing continues at a step 340, at which the HRU controller signals the HRU condenser to increase a rate of HRU medium flow by a preset increase flow increment (X3) in order to decrease the refrigerant vapor pressure and thereby decrease processing unit temperatures. This reduces extreme temperatures of processing units, thereby balancing the temperatures of the processing units before further temperature increases are made.

Subsequently, at a step 350, the HRU determines which processing units are thermally throttled by a preset lower throttle limit (X5), and the HRU controller signals all such processing units to reduce their user-throttled maximum frequency by a preset user-throttle increment (X4).

Next, at a step 360, the HRU signals the HRU condenser to reduce the rate of HRU medium flow by a preset decrease flow increment (X6). This step increases the vapor pressure of the refrigerant, thereby increasing temperatures of all processing units. Through multiple reiteration of this step at each cycle of the process (i.e., steps 310-360), the temperature of all processing units is incrementally increased in a balanced manner to maximize the refrigerant temperature for heat reuse.

If at step 330 no processing units were throttled by more than the preset upper thermal throttle limit, then step 340 may be skipped and the processing may continue directly at step 350. (Alternatively, processing may continue directly at step 360.)

Steps 310-360 are repeated until determining at step 320 that that the number of thermally and user throttled processing units is at least equal to the preset maximum of throttled processing units. The HRU controller may then, at a step 370, maintain the refrigerant and HRU media flow rates, as well as the processing unit maximum frequencies, at least until a predetermined amount of time has pass for repeating the steps 310-360 to rebalance processing unit temperatures. The HRU controller may also output, to a log or to a system administrator, statistics of processing unit temperatures, such as mean and standard deviation, as well as statistics related to the processing unit frequency settings and the HRU medium flow rates.

For a typical data center, the preset maximum of throttled processing units (X1) may be set, for example, to between 20 and 40 percent, with 30 percent being a typical value. The preset upper thermal throttle limit (X2) may be set, for example, to between 5 and 20 percent, with 10 percent being typical.

The preset increase flow increment (X3) may be set, for example to between 1 and 10 percent (5% being typical).

The preset user throttle increment (X4) may be set, for example to between 1 and 10 percent (typically 5%).

The preset lower thermal throttle limit (X5) may be set, for example to between 1 and 10 percent (typically 5%).

The preset decrease flow increment (X6) may be set, for example to between 1 and 10 percent (5% being typical).

As will be understood with reference to the above description and the referenced drawings, embodiments of computer-implemented methods are provided herein, some of which may be performed by various configurations of apparatus and systems described herein and some of which can be performed according to instructions stored in non-transitory computer readable storage media. Moreover, some embodiments of computer-implemented methods provided herein can be performed by other devices or systems and can be performed according to instructions stored in computer-readable storage media other than that described herein, as will become apparent to those having skill in the art with reference to the embodiments described herein. Any reference to systems and computer-readable storage media with respect to the following computer-implemented methods is provided for explanatory purposes, and is not intended to limit any of such systems and any of such non-transitory computer-readable storage media with regard to embodiments of computer-implemented methods described above. Likewise, any reference to the following computer-implemented methods with respect to systems and computer-readable storage media is provided for explanatory purposes, and is not intended to limit any of such computer-implemented methods disclosed herein.

The flowcharts and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. As used herein, the singular form “a”, “an” and “the” include plural references unless the context clearly dictates otherwise.

The word “exemplary” as used herein means “serving as an example, instance or illustration,” and is not necessarily to be construed as preferred or advantageous over other embodiments or to exclude the incorporation of features from other embodiments.

It is appreciated that certain features that are, for clarity, described in the context of separate embodiments may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments, unless the embodiment is inoperative without those elements.

The processes described above can be performed by software and/or hardware. These processes and portions thereof can be performed by computers, computer-type devices, workstations, processors, micro-processors, other electronic searching tools and memory and other non-transitory storage-type devices associated therewith. The processes and portions thereof can also be embodied in programmable non-transitory storage media, for example, compact discs (CDs) or other discs including magnetic, optical, etc., readable by a machine or the like, or other computer usable storage media, including magnetic, optical, or semiconductor storage, or other source of electronic signals.

The processes (methods) and systems, including components thereof, herein have been described with exemplary reference to specific hardware and software. The processes (methods) have been described as exemplary, whereby specific steps and their order can be omitted and/or changed by persons of ordinary skill in the art to reduce these embodiments to practice without undue experimentation. The processes (methods) and systems have been described in a manner sufficient to enable persons of ordinary skill in the art to readily adapt other hardware and software as may be needed to reduce any of the embodiments to practice without undue experimentation and using conventional techniques. Processing elements of the system described herein may be implemented in digital electronic circuitry, or in computer hardware, firmware, software, or in combinations thereof. Such elements can be implemented as a computer program product, tangibly embodied in an information carrier, such as a non-transient, machine-readable storage device, for execution by, or to control the operation of, data processing apparatus, such as a programmable processor, computer, or deployed to be executed on multiple computers at one site or one or more across multiple sites. Memory storage for software and data may include multiple one or more memory units, including one or more types of storage media. Examples of storage media include, but are not limited to, magnetic media, optical media, and integrated circuits such as read-only memory devices (ROM) and random access memory (RAM). Network interface modules may control the sending and receiving of data packets over networks. Mobile devices may be any computing device permitting user input to interactive applications as described above. Method steps associated with the system and process can be rearranged and/or one or more such steps can be omitted to achieve the same, or similar, results to those described herein.

It is to be understood that the embodiments described hereinabove are cited by way of example, and that the present invention is not limited to what has been particularly shown and described hereinabove.

The following table includes definitions of the numeric indicators used in the figures:

| Numeric | |
|---|---|
| Indicator | Name of Element |
| 100 | System for data center heat reuse |
| 102 | Data center |
| 104 | District Heating Facility |
| 106 | Server rack (set of multiple servers) |
| 114 | Server |
| 116 | Processing unit (PU) package |
| 118 | 2-phase evaporator |
| 120 | Refrigerant |
| 120A | “Cold” refrigerant liquid (from Condenser) |
| 120B | “Hot” refrigerant vapor (from Evaporator) |
| 130 | HRU condenser |
| 134 | HRU condenser medium (e.g., air or water) |
| 134A | Condenser inlet stream (cold) |
| 134B | Condenser outlet stream (hot) |
| 150 | HRU Controller |
| 202 | processing unit (PU) chip/die |
| X₁ | preset maximum of throttled processing units |
| X₂ | preset upper thermal throttle limit |
| X₃ | preset increase flow increment |
| X₄ | preset user throttle increment |
| X₅ | preset lower thermal throttle limit |
| X₆ | preset decrease flow increment |

1. A system for controlling data center heat reuse comprising:
multiple evaporators units (EUs), each configured to operate as a two-phase evaporator, each of the multiple EUs affixed to a respective processing unit package of a data center server to draw heat from the respective processing unit package;
a heat reuse unit (HRU) condenser, configured to provide refrigerant liquid to the multiple EUs and to receive heated refrigerant vapor from the multiple EUs, and further configured to release heat from the heated refrigerant vapor to an HRU medium providing heat to a reuse application; and
an HRU controller, including non-transient memory storage having programmed instructions that when executed by the HRU controller perform steps of:
1) receiving temperature and frequency data from all processing units of the processing unit packages [Step 310];
2) determining that a number of processing units that are thermally and/or user-throttled is less than a preset maximum of throttled processing units (X₁) and that at least one processing unit is thermally throttled by more than a preset upper thermal throttle limit (X₂) [Steps 320 and 330];
3) responsively signaling the HRU condenser to increase a rate of HRU medium flow by a preset increase flow increment (X₃) [Step 340];
4) subsequently signaling all processing units that are thermally throttled by at least a preset lower thermal throttle limit (X₅) to reduce their user-throttled maximum frequency by a preset user-throttle increment (X₄) [Step 350];
5) subsequently, signaling the HRU condenser to reduce the rate of HRU medium flow by a preset decrease flow increment (X₆) [Step 360];
6) repeating the above steps until determining at step 2 that the number of thermally and user throttled processing units is at least equal to the preset maximum of throttled processing units (X₁) [Step 320].

2. The system of claim 1, wherein the instructions further comprise an alternative process of determining at step 2 that no processing units are thermally throttled by more than the preset outlier thermal throttle limit (X₂) and responsively proceeding directly to step 5.

3. The system of claim 1, further comprising maintaining the rate of HRU medium flow and the user maximum processing unit frequency settings, responsively to determining at step 2 that the number of thermally and user throttled processing units is at least equal to the preset maximum of throttled processing units (X₁) [Step 370].

4. The system of claim 1, further comprising outputting statistics of processing unit temperatures, including mean and standard deviation of processing unit temperatures, responsively to determining at step 2 that the number of thermally and user throttled processing units is at least equal to the preset maximum of throttled processing units (X₁).

5. The system of claim 1, wherein the preset maximum of throttled processing units (X₁) is preset at a level to maintain service level agreement (SLA) requirements.

6. The system of claim 1, wherein the preset maximum of throttled processing units (X₁) is set to 30 percent.

7. The system of claim 1, wherein the preset upper thermal throttle limit (X₂) is set to 10 percent.

8. The system of claim 1, wherein the preset increase flow increment (X₃) is set to 5 percent.

9. The system of claim 1, wherein the preset user throttle increment (X₄) is set to 5 percent.

10. The system of claim 1, wherein the preset lower thermal throttle limit (X₅) is set to 5 percent.

11. The system of claim 1, wherein the preset decrease flow increment (X₆) is set to 5 percent.

12. The system of claim 1, wherein the preset maximum of throttled processing units (X₁) is set to between 20 and 40 percent.

13. The system of claim 1, wherein the preset upper thermal throttle limit (X₂) is set to between 5 and 20 percent.

14. The system of claim 1, wherein the preset increase flow increment (X₃) is set to between 1 and 10 percent.

15. The system of claim 1, wherein the preset user throttle increment (X₄) is set to between 1 and 10 percent.

16. The system of claim 1, wherein the preset lower thermal throttle limit (X₅) is set to between 1 and 10 percent.

17. The system of claim 1, wherein the preset decrease flow increment (X₆) is set to between 1 and 10 percent.
